(19) United States
(12) Patent Application Publication
(10) Pub. No.: US 2025/0203935 A1
(43) Pub. Date: Jun. 19, 2025

(54) SELF-ALIGNED DIELECTRIC ISOLATION ON SOURCE/DRAINS

(71) Applicant: International Business Machines Corporation, Armonk, NY (US)

(72) Inventors: Shay Reboh, Guilderland, NY (US); Ruilong Xie, Niskayuna, NY (US); Shahrukh Khan, Sandy Hook, CT (US)

(21) Appl. No.: 18/542,928

(22) Filed: Dec. 18, 2023

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0135; H10D 84/0147; H10D 84/0149; H10D 84/038; H10D 84/83

(57) ABSTRACT

A semiconductor structure that includes a semiconductor element, where a portion of the semiconductor element extends into a metal element of the semiconductor structure. The semiconductor structure includes a dielectric material on the portion of the semiconductor element extending into the metal element. The dielectric material on the portion of the semiconductor element is formed with a self-limiting plasma process. The semiconductor element can be a source/drain of a field-effect transistor. The portion of semiconductor element such as a source/drain covered by the dielectric material extends into the metal element, such as an adjacent via. The dielectric material electrically isolates the portion of the source/drain extending into the via from shorting to the via. The field-effect transistor may be at least one of two vertically stacked field-effect transistors. The ability to electrically insulate the portions of the source/drain extending into adjacent vias allows densely packed vertically stacked gate-all-around transistors.

### BACKGROUND

The disclosure relates generally to forming semiconductor devices with a self-aligned dielectric material as a spacer on one or more sidewalls of source/drains, and more specifically, to forming the dielectric material on the exposed surfaces of source/drain sidewalls during via and contact formation to electrically isolate the source/drains from metal vias and contacts.

As the semiconductor industry technology continues scaling according to Moore's law, significant challenges arise as the industry looks beyond the five nanometer (nm) technology node. With increasing demands to reduce the dimensions of semiconductor devices, nanosheet field-effect transistors (FETs) and stacked nanosheet FETs help achieve a reduced device footprint while maintaining device performance. A typical nanosheet FET includes a plurality of stacked nanosheets extending between a pair of source/drain epitaxial regions. The nanosheet FET device may be a gate-all-around device in which a gate surrounds the channels of the nanosheet FET devices.

The gate-all-around (GAA) nanosheet metal-oxide-semiconductor field-effect transistor (MOSFET) structures have been recognized as excellent candidates to achieve improved power performance and area scaling compared to the current finFET technologies. Specifically, nanosheet-based semiconductor structures such as GAA nanosheet MOSFETs provide high drive currents due to wide effective channel width (Weff) while maintaining short-channel control. The complementary field-effect transistor (CFET) is composed of two stacked complementary FETs, where the stacked complementary FET includes a p-type FET (PFET) and an n-type FET (NFET) that are vertically stacked further improve device density. Instead of stacking either n-type devices on top of other n-type devices or stacking p-type devices on other p-type devices as occurs with conventional vertically stacked GAA nanosheet transistors, CFET devices stack both n-type and p-type devices on top of each other. CFET stacked transistors offer a scaling path by stacking the NFET and PFET over each other, thereby providing an area benefit.

Additionally, as the semiconductor industry continues to drive beyond the 5 nm technology node to the two nm technology node with increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. A backside power delivery network improves semiconductor device gate delay and reduces BEOL wiring congestion.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later.

Aspects of the disclosed invention relate to a semiconductor structure that includes a semiconductor element, where a portion of the semiconductor element extends into a metal element of the semiconductor structure. The semiconductor structure includes a dielectric material on the portion of the semiconductor element contacts the metal element.

Aspects of the present invention relate to two sets of vertically stacked gate-all-around field-effect transistors where a first set of the vertically stacked gate-all-around field-effect transistor is a first L-shaped stack of two gate-all-around field-effect transistors. The first L-shaped stack is composed of a first top gate-all-around field-effect transistor over a first bottom gate-all-around field-effect transistor, where a first top source/drain has a narrower width than a width of a first bottom source/drain. The second set of the vertically stacked gate-all-around field-effect transistor is a second L-shaped stack of two more gate-all-around field-effect transistor. The second L-shaped stack is composed of a second top stacked gate-all-around field-effect transistor over a second stacked gate-all-around field-effect transistor, wherein the second top source/drain has a narrower width than the width of a second bottom source/drain. In the first L-shaped stack, the top source/drain of the first top gate-all-around field-effect transistor has a dielectric material on a left sidewall. The dielectric material contacts a left via. A right sidewall of the top source/drain of the first top gate-all-around field-effect transistor contacts a center via. The bottom source/drain of the first bottom gate-all-around field-effect transistor has the dielectric material on the right sidewall, where the dielectric material electrically isolates the bottom source/drain of the first bottom gate-all-around field-effect transistor from a backside power via.

Aspects of the present invention provide a method of a forming a conformal, self-aligned dielectric material on a source/drain of two vertically stacked gate-all-around transistors formed using known nanosheet gate-all-around transistor semiconductor manufacturing processes, where the bottom source/drain of the bottom gate-all-around transistor is wider than the top source/drain of the top gate-all-around transistor. The method includes etching a first via hole down to a top surface of the bottom gate-all-around transistor, where the top source/drain of the top gate-all-around transistor extends into a portion of the via hole. The method includes performing a low temperature plasma process on the two vertically stacked gate-all-around transistors, where the low temperature plasma process forms a layer of a dielectric material as a spacer on the exposed surfaces of the top source/drain of the top gate-all-around transistor where the exposed surfaces of the top source/drain the sidewalls of the top source/drain that extend into the portion of the via hole. The method includes depositing a metal material in the via hole, where the metal material is isolated from the top source/drain by the layer of the dielectric material. The method includes forming a via. The via contacts the layer of the dielectric material, a top surface of a bottom source/drain of the bottom gate-all-around transistor, and a contact connecting to the frontside interconnect wiring. The layer of the dielectric material forming a spacer isolates the top source/drain extending into a portion of the via hole from the metal material of the completed via.

### BRIEF DESCRIPTION OF THE DRAWINGS

The above and other aspects, features, and advantages of various embodiments of the present invention will be more apparent from the following description taken in conjunction with the accompanying drawings.

FIG. 1 illustrates a top view of a semiconductor design of a stacked field-effect transistor, in accordance with an embodiment of the present invention.

FIG. 2A depicts a cross-sectional view, along section line X of FIG. 1 and FIG. 2B depicts a cross-sectional view, along section line Y of FIG. 1 of the semiconductor structure after patterning a top nanosheet stack stacked on a bottom nanosheet stack, in accordance with an embodiment of the present invention.

FIG. 3A depicts a cross-sectional view, along section line X of FIG. 1 and FIG. 3B depicts a cross-sectional view, along section line Y of FIG. 1 of the semiconductor structure after forming dummy gates, in accordance with an embodiment of the present invention.

FIG. 4A a cross-sectional view, along section line X of FIG. 1 and FIG. 4B depicts a cross-sectional view, along section line Y of FIG. 1 of the semiconductor structure after forming replacement metal gates, in accordance with an embodiment of the present invention.

FIG. 5A depicts a cross-sectional view, along section line X of FIG. 1, FIG. 5B depicts a cross-sectional view, along section line Y of FIG. 1, and FIG. 5C of the semiconductor structure after etching holes for contacts and performing a low temperature plasma oxidation of exposed portions of the stacked source/drains (S/Ds), in accordance with an embodiment of the present invention.

FIG. 6A depicts a cross-sectional view, along section line X of FIG. 1, FIG. 6B depicts a cross-sectional view, along section line Y of FIG. 1, and FIG. 6C depicts a cross-sectional view, along section line C of FIG. 1, of the semiconductor structure after forming a plurality of vias and contacts, in accordance with an embodiment of the present invention.

FIG. 7A depicts a cross-sectional view, along section line X of FIG. 1, FIG. 7B depicts a cross-sectional view, along section line Y of FIG. 1, and FIG. 3C depicts a cross-sectional view, along section line C of FIG. 1 of the semiconductor structure after forming one or more layers of frontside interconnect wiring and bonding a carrier wafer, in accordance with an embodiment of the present invention.

FIG. 8A a cross-sectional view, along section line X of FIG. 1, FIG. 8B depicts a cross-sectional view, along section line Y of FIG. 1, and FIG. 8C depicts a cross-sectional view, along section line C of FIG. 1 of the semiconductor structure after removing the semiconductor substrate and depositing a backside interlayer dielectric (BILD), in accordance with an embodiment of the present invention.

FIG. 9A depicts a cross-sectional view, along section line X of FIG. 1, FIG. 9B depicts a cross-sectional view, along section line Y of FIG. 1, and FIG. 9C depicts a cross-sectional view, along section line C of FIG. 1, the semiconductor structure after forming a backside contact and a first backside metal layer, in accordance with an embodiment of the present invention.

FIG. 10A depicts a cross-sectional view, along section line X of FIG. 1, FIG. 10B depicts a cross-sectional view, along section line Y of FIG. 1, and FIG. 10C depicts a cross-sectional view, along section line C of FIG. 1 of a semiconductor structure with two staggered, stacked semiconductor devices, in accordance with an embodiment of the present invention.

FIG. 11 depicts a cross-sectional view, along section line C2 a semiconductor structure with four nanosheet GAA FETs where two of the top nanosheet GAA FETs are each stacked on a bottom nanosheet GAA FET, in accordance with an embodiment of the present invention.

FIG. 12 depicts a cross-sectional view of a semiconductor structure after forming a metal element in ILD directly contacting a dielectric material on semiconductor element, in accordance with an embodiment of the present invention.

### DETAILED DESCRIPTION

Embodiments of the present invention recognize that in following Moore's law, numerous technological strides have been made in the semiconductor industry to create even smaller transistors, fitting more transistors in the same area, while reducing the power consumption of these evolving transistors and resulting semiconductor devices. For the evolution of reduced size transistors, semiconductor technology has evolved from planar transistor designs to three-dimensional type finFET designs which are further evolving into stacked semiconductor devices. Embodiments of the present invention recognize that 3D-stacked semiconductor devices such as stacked gate-all-around field-effect transistors (GAA FETs) and complementary field-effect transistors (CFET) will be the key to continuing to extend Moore's Law. When semiconductor devices are densely packed semiconductor devices such as GAA FETs or CFETs, an increased risk of shorting the source/drains to the vias or contacts connecting to adjacent semiconductor devices or interconnect wiring. The risk of shorting source/drains into adjacent metal vias or contacts limits cell scaling of the semiconductor devices. A method of reducing cell scaling and increasing semiconductor device density would be desirable.

Embodiments of the present invention provide a method of creating a semiconductor structure that prevents shorting of a semiconductor element such as the source/drains of a semiconductor device to a metal element or feature such as a via, a contact, or a portion of a metal line that is immediately adjacent to the semiconductor element that can be a source/drain. Embodiments of the present invention provide a method of forming a thin, conformal layer of a dielectric material on exposed portions of a semiconductor element such as a source/drain or channel that extends into an opening or hole for an adjacent via, contact, or line. A low temperature plasma process such as a low temperature plasma oxidation process or a low temperature plasma nitridation process is performed and a thin, conformal layer of a dielectric material such as an oxide is formed. The low temperature plasma process is self-limiting and forms a thin layer of the dielectric material that typically in the range of 3-5 nanometers (nm) on exposed surfaces of the semiconductor element. The low temperature plasma process is self-aligning as it only forms the dielectric material on the exposed surfaces of the semiconductor material such as a source/drain or a channel.

The disclosed method of forming the dielectric material as a spacer on the exposed surfaces of the semiconductor material of the source/drain ensures that shorting of the source/drain to any adjacent metal element or via cannot occur. Providing any exposed surfaces of the source/drain in via holes or other types of trenches before via, contact, or metal line formation prevents shorting and allows more densely packed semiconductor devices. Using the methods disclosed herein any semiconductor element such as a source/drain extending into a via, a contact, or a metal line would be electrically isolated by the dielectric material such as an oxide or a nitride formed in the low temperature plasma process.

Embodiments of the present invention disclose forming the dielectric material as a spacer on the sidewalls of one or more source/drains of one or more vertically stacked gate-all-around field-effect transistors (GAA FETS) extending to a metal via, a backside power via, or a contact where the dielectric material electrically isolates each of the source/drains extending into the metal via, the backside power via, or a contact. Electrically isolating the source/drains of the vertically stacked GAA FETs from the via or contact metal when the source/drains of tightly packed and stacked GAA FETs prevent shorting of the source/drains to the vias or contacts when the source/drains extend into or overlap the via holes and the completed vias or contacts.

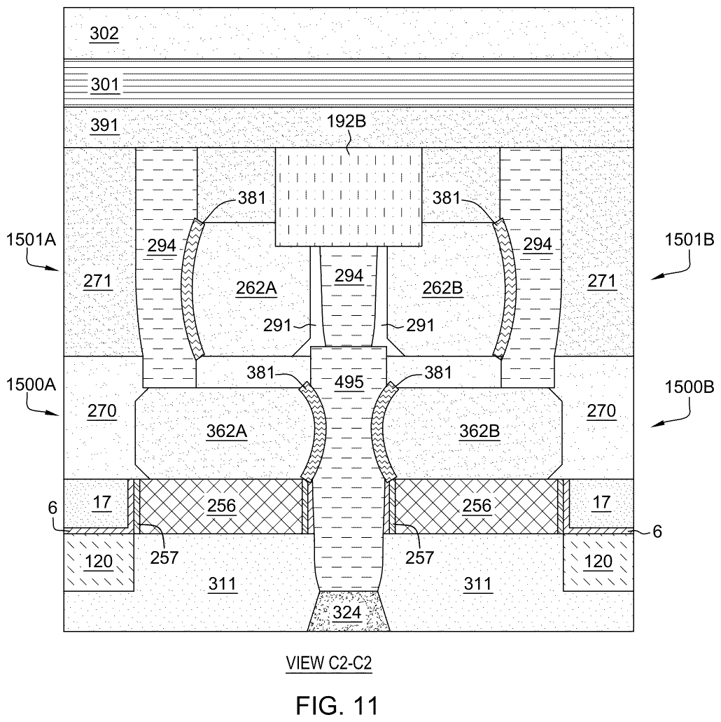

While the method of forming the dielectric material as a spacer on one or more source/drains extending into a via, a contact, or a backside power via is discussed in reference to two vertically stacked GAA FETs or two sets of two vertically stacked and staggered GAA FETs (e.g., four GAA FETs as depicted in FIG. 11), in other embodiments, the methods discussed herein to form the dielectric material as a spacer on exposed surfaces of a semiconductor material such as a source/drain or a channel can be applied other semiconductor devices and other stacked semiconductor devices such as finFETs, planar FETs, complementary metal-oxide semiconductor (CMOS) logic devices, and forksheet FETs to provide more densely packed semiconductor devices and reduced cell scaling.

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

It is to be understood that aspects of the present invention will be described in terms of a given illustrative architecture; however, other architectures, structures, substrate materials, process features, and steps can be varied within the scope of aspects of the present invention.

It will also be understood that when an element such as a layer, region, or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Methods as described herein can be used in the fabrication of integrated circuit chips also known as a semiconductor chip. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

The terminology used herein is for the purpose of describing particular embodiments only and is not tended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for case of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below,” or “beneath” other elements or features would then be oriented “above” the other elements or features. Thus, the term “below” can encompass both an orientation of above and below. The device can be otherwise oriented (rotated 90 degrees or at other orientations and the spatially relative descriptors used herein can be interpreted accordingly. In addition, be understood that when a layer is referred to as being “between” two layers, it can be the only layer between the two layers, or one or more intervening layers can also be present. In embodiments, elements labeled with similar numbers such as 62A and 162A can be similar elements.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Various materials are referred to herein as being “removed” or “etched” whereas etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using a plasma.

It should also be understood that material compounds will be described in terms of listed elements, e.g., SiGe. These compounds include different proportions of the elements within the compound, e.g., SiGe includes SixGe1-x where x is less than 1, etc. In addition, other elements can be included in the compound and still function in accordance with the present principles. The compounds with additional elements will be referred to herein as alloys.

Reference is now made to the figures. The figures provide schematic cross-sectional illustrations of semiconductor devices at intermediate stages of fabrication, according to one or more embodiments of the invention. The device provides schematic representations of the devices of the invention and are not to be considered accurate or limiting with regard to device element scale.

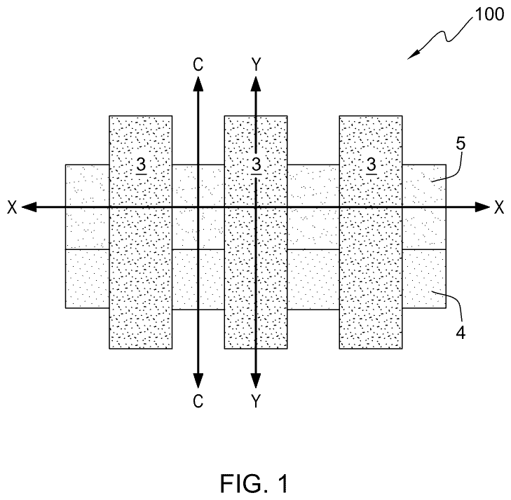

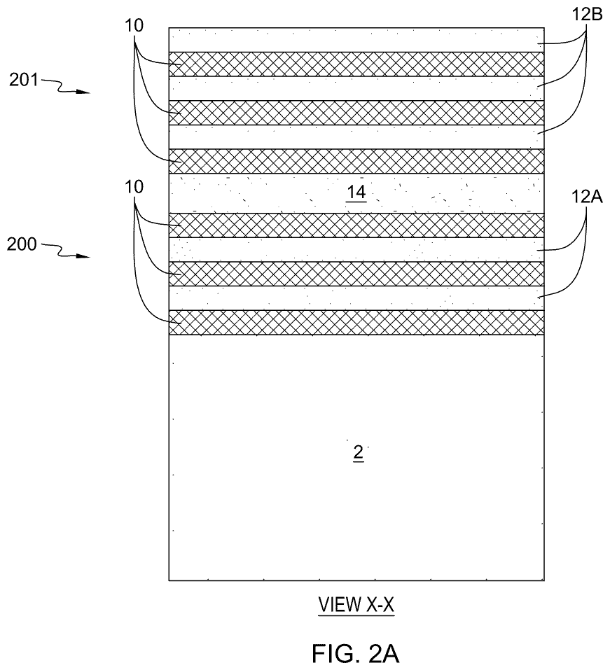

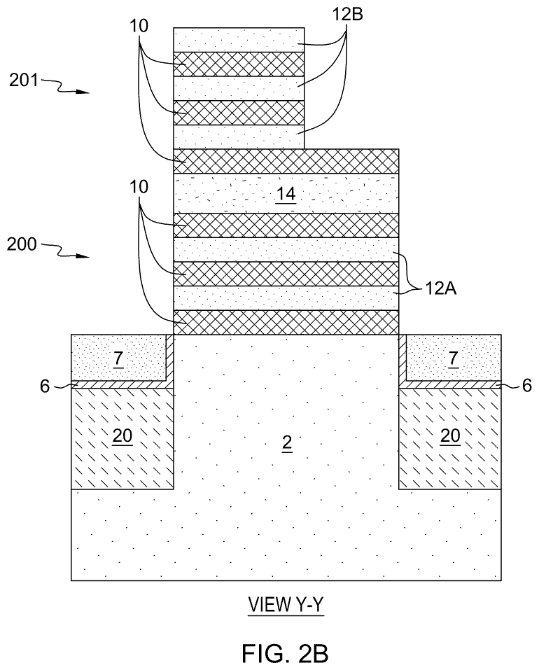

FIG. 1 illustrates a top standard cell view of a stacked field-effect transistor 100, in accordance with an embodiment of the present invention. As depicted, FIG. 1 includes gate structures 3, active region 4, and active region 5 where active region 4 can be under active region 5. In other embodiments of the present invention, the processes described hereinafter can be applied to a single, unstacked FET with active region, multi-stacked FETs with more than two stacked FETs, a planar FET, a forksheet FET, or a complementary FET (CFET) but is not limited to these device types. Also illustrated in FIG. 1 are the locations of cross-sectional views through line X-X, cross-sectional views through line Y-Y, and cross-sectional views through lines C-C. In the following FIGS. 2-12, FIGs. with a figure number including “A” are cross-sectional views along section line X, FIGs. with figure numbers including “B” are cross-sectional views along section line Y, and FIGs. with a figure number including “C” are cross-sectional views along section line C.

As depicted in FIG. 1, cross-sectional views along section line X are perpendicular to gate structures 3 and through active region 5. Cross-sectional views along section line Y are through and along one of gate structures 3. Therefore, cross-sectional views along section line Y are parallel to and through one of gate structures 3. As depicted in FIG. 1, cross-sectional views along section line C are parallel to gate structures 3 and between two adjacent gate structures 3. The cross-sectional views along section line C are through active region 5 and active region 4. Active region 4 and active region 5 are vertically stacked with active region 4 above active region 5.

FIG. 2A depicts a cross-sectional view, along section line X of FIG. 1 and FIG. 2B depicts a cross-sectional view, along section line Y of FIG. 1 of the semiconductor structure after patterning top nanosheet stack 201 above bottom nanosheet stack 200, in accordance with an embodiment of the present invention. Top nanosheet stack 201 and bottom nanosheet stack 200 can be formed using known nanosheet materials and formation processes commonly used in to form stacked gate-all-around field-effect transistors (GAA FETs) and complimentary FETs (CFETs). While FIG. 2A and FIG. 2B depict bottom nanosheet stack 200 and top nanosheet stack 201, in other embodiments, more than two nanosheet stacks are present in the semiconductor structure (e.g., three or four nanosheet stacks can vertically stacked on substrate 2).

FIG. 2A includes top nanosheet stack 201 which is composed of channels 12B and sacrificial layers 10 B and bottom nanosheet stack 200 which is composed of channels 12A and sacrificial layers 10. Also, included in FIG. 2A is sacrificial material 11 between top nanosheet stack 201 and bottom nanosheet stack 200 on substrate 2.

Substrate 2 can be composed of any semiconductor material used in forming semiconductor chips. In various embodiments, substrate 2 is composed of silicon. Channels 12A and 12B are a nanosheet layer composed of a semiconductor material. Channels 12A and 12B are nanosheet layers that may be grown by known nanosheet semiconductor epitaxy processes such as molecular beam epitaxy (MBE). In various embodiments, channels 12A and 12B are composed of silicon but are not limited to a silicon semiconductor material. The semiconductor material of channels 12A and 12B have a different etch sensitivity and/or etch rate than substrate 2, sacrificial layers 10, and center sacrificial material 11. In various embodiments, channels 12A and channels 12B are doped. For example, channels 12A may be doped with a n-type dopant and channels 12B may be doped with a p-type dopant or vice versa.

Sacrificial layers 10 are nanosheet layers composed of a semiconductor material that can be grown using one of known epitaxy processes. In various embodiments, sacrificial material 11 is composed of SiGe. Sacrificial layers 10 have a different etch sensitivity than center sacrificial material 11 and substrate 2. In various embodiments, center sacrificial material 11 can also be composed of SiGe and can have different amounts of Si and Ge than sacrificial layers 10.

FIG. 2B includes oxide 7 with liner 6 (e.g., SiN) and shallow trench isolation (STI) 20 in substrate 2. In FIG. 2B, top nanosheet stack 201 and bottom nanosheet stack 200 can be patterned and etched (e.g., by RIE). As depicted in FIG. 2B, portions of channels 12B and two of the top three layers of sacrificial layers 10 can be removed so that the remaining portion of top nanosheet stack 201 is narrower than the remaining portion of bottom nanosheet stack 200.

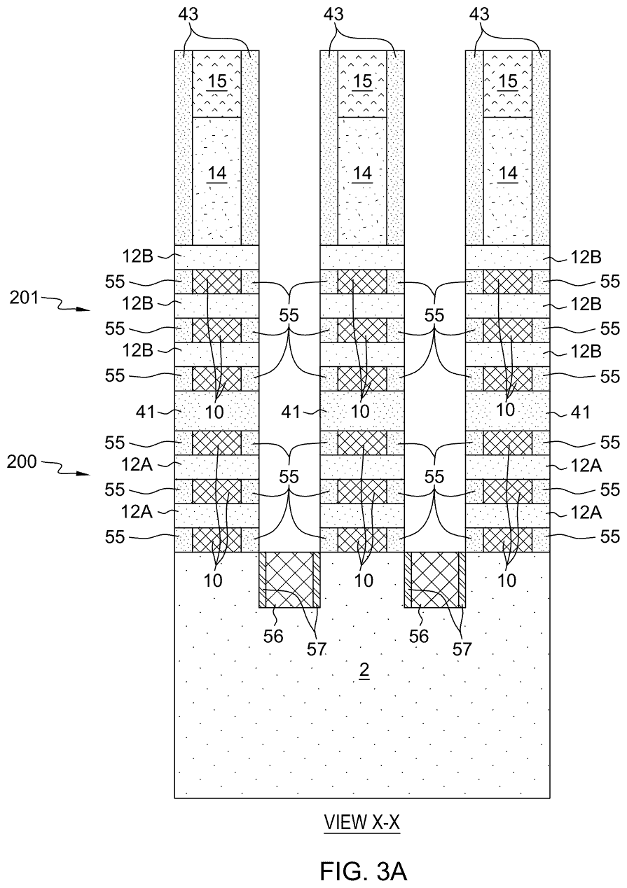

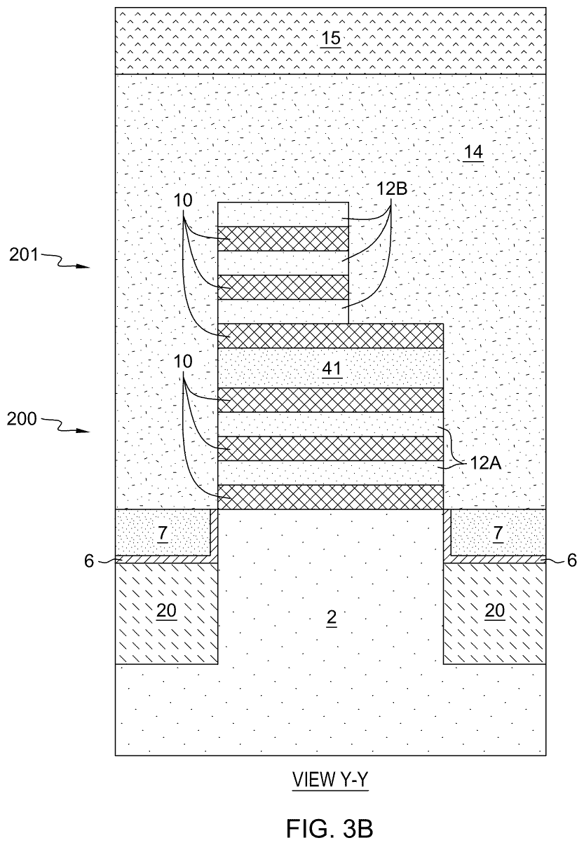

FIG. 3A depicts a cross-sectional view, along section line X of FIG. 1 and FIG. 3B depicts a cross-sectional view, along section line Y of FIG. 1 of the semiconductor structure after forming dummy gates 14 with gate spacer 43, and inner spacers 55 covered by hardmask (HM) 15, in accordance with an embodiment of the present invention.

Using known nanosheet GAA FET formation processes, dummy gate 14 with inner spacers 55, gate spacer 43, and HM 15 can be formed. Portions of top nanosheet stack 201, bottom nanosheet stack 200, and a portion of substrate 2 of FIG. 3A can be removed (e.g., by RIE and/or IBE), sacrificial layers 10 can be recessed, sacrificial material 11 removed, and middle dielectric isolation (MDI) 41 deposited with inner spacers 55, gate spacer 43, inner spacers 55 deposited, placeholder 56 formed (e.g., by silicon etch and epitaxy) with liners 57, and dummy gates 14 with HM 15 deposited. Placeholders 56 may be composed of a semiconductor material such as SiGe.

In FIG. 3B, using known deposition processes, dummy gate 14 can be deposited over oxide 7, a portion of a bottom layer of sacrificial layers 10 in top nanosheet stack 201, and around the exposed sidewalls of top nanosheet stack 201 and bottom nanosheet stack 200. HM 15 can be deposited over dummy gate 14.

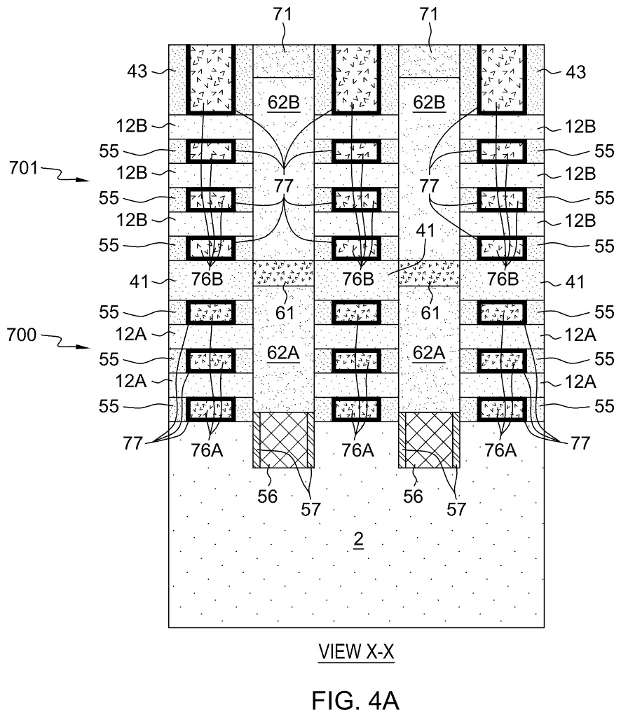

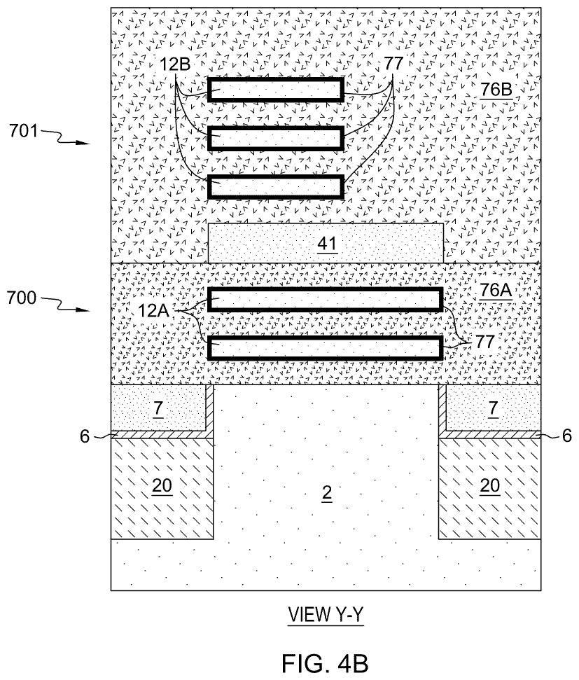

FIG. 4A a cross-sectional view, along section line X of FIG. 1 and FIG. 4B depicts a cross-sectional view, along section line Y of FIG. 1 of the semiconductor structure after forming top GAA FET 701 and bottom GAA FET 700, in accordance with an embodiment of the present invention. Using known semiconductor processes for forming nanosheet GAA FETs, top GAA FET 701 and bottom GAA FET 700 can be created. Forming GAA FET 701 and bottom GAA FET 700 can include forming source/drains (S/D) 62A and S/D 62B along with forming replacement metal gate structures composed of gate metal 76A and gate metal 76B with gate dielectric 77, gate spacers 43, and inner spacers 55. For example, as depicted in FIGS. 4A and 4B, dummy gates 14 with HM 15 and sacrificial layers 10 can be removed, and gate dielectric 77 and gate metal 76B and gate metal 76A can be deposited for the metal replacement gates formed in both top GAA FET 701 and bottom GAA FET 700, respectively.

In various embodiments, gate metal 76B is a work function metal (WFM) and gate metal of top GAA FET 701 and gate metal 76A is the WFM and gate metal in bottom GAA FET 700. The work function metal for gate metal 76B and gate metal 76A can be the same type WFM (e.g., both are n-type WFM to form stacked GAA FETs 700 and 701) or the WFM can be different types (e.g., gate metal 76B includes a n-type WFM and gate metal 76A includes a p-type WFM for CFETs).

As depicted in FIG. 4A, S/D 62B and S/D 62A of top GAA FET 701 and bottom GAA FET 700, respectively, can be separated by dielectric isolation 61 while the top portion of gate metal 76A covered by gate dielectric 77 can be separated from the bottom portion of gate metal 76B covered by gate dielectric 77 in bottom GAA FET 700 by MDI 41. ILD 71 resides on S/D 62B. The dielectric material deposited for dielectric isolation 61 can be one or more of a nitride, an oxide, or a lower-k nitride material.

FIG. 4B depicts top GAA FET 701 with at least gate metal 76B, gate dielectric 77, channels 12B while bottom GAA FET 700 includes at least gate metal 76A and gate dielectric 77 on substrate 2 with STI 20 and oxide 7.

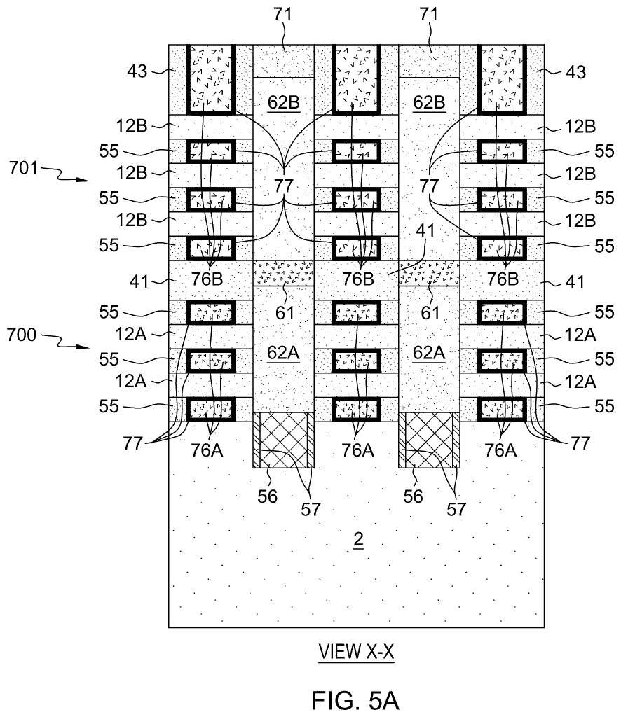

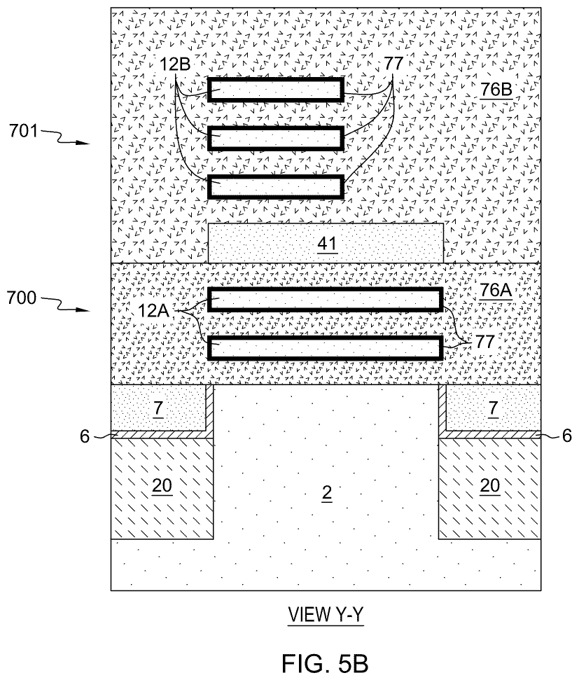

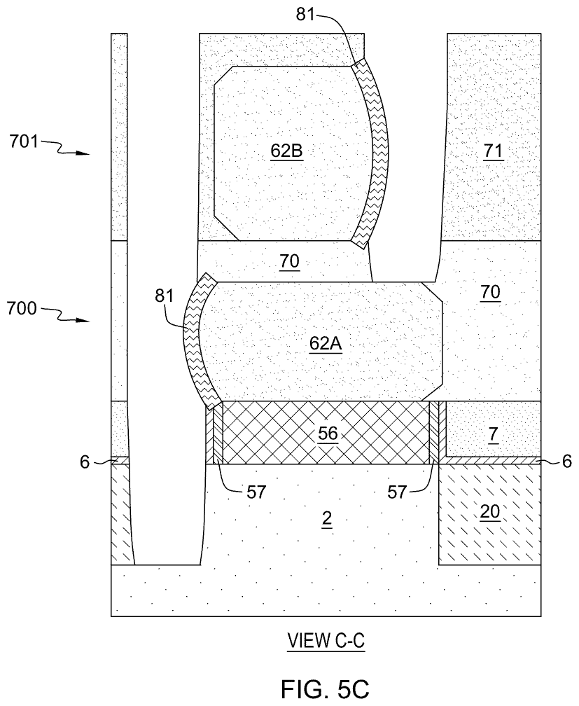

FIG. 5A depicts a cross-sectional view, along section line X of FIG. 1, FIG. 5B depicts a cross-sectional view, along section line Y of FIG. 1, and FIG. 5C depicts a cross-sectional view, along section line X of FIG. 1 of the semiconductor structure after etching holes for contacts and performing a low temperature plasma oxidation of exposed portions of the stacked source/drains (S/Ds), in accordance with an embodiment of the present invention. As depicted, the elements of FIG. 5A and FIG. 4A are the same. Similarly, the elements of FIG. 5B and FIG. 4B are the same.

The source/drain cut, depicted as section line C in FIG. 1, provides the cross-sectional view depicted in FIG. 5C. The via hole etching processes expose the sidewalls of S/D 62A and S/D 62B, along with a top surface of S/D 62A to the low temperature plasma oxidation process.

As depicted in FIG. 5C, bottom dielectric 70 is between S/D 62B and S/D 62A (e.g., S/D 62B resides on a portion of bottom dielectric 70). Bottom dielectric 70 can be any suitable dielectric material such as an interlayer dielectric material. Using one or more known via and contact hole wet and/or dry etching processes, a leftmost bottom via hole or opening for a backside power via is formed under a via hole extending to the top surface of ILD 71. The leftmost via hole for the backside power via extends down through oxide 7 and STI 20 into a portion of substrate 2. A portion of the leftmost via hole exposes a sidewall or a portion of a sidewall of S/D 62A. In various embodiments, a portion of S/D 62A extends into an adjacent via hole. In other embodiments, the sidewall of S/D 62A is parallel to the adjacent via hole and forms a portion of the via hole sidewall (e.g., the sidewall of S/D 62A is flush with the adjacent via hole). The rightmost via hole extends down to the top surface of S/D 62A and exposes a sidewall of S/D 62B. In various embodiments, at least a portion of one sidewall of S/D 62A or S/D 62B extends into at least one via hole or opening for a metal element such as a contact or a portion of a metal layer (e.g., a line). The portion of the sidewall of S/D 62A and S/D 62B that protrudes into the via hole can be a curved, pointed, a portion of a hexagon, or rounded pointed portion of S/D 62A or 62B. In one embodiment, the sidewall of one or both of S/D 62A and 62B are straight, vertical sidewalls.

After forming the via holes, a low temperature plasma oxidation process occurs to form a thin layer of an oxide material such as dielectric material 81 on the exposed surfaces of S/D 62A and S/D 62B. In some cases, a low temperature plasma nitridation process can be used to form a nitride material for dielectric material 81. Dielectric material 81, as formed, can be a thin, self-aligned, conformal layer formed using a self-limiting process (e.g., low temperature plasma oxidation process or a plasma nitridation). Dielectric material 81 can be an oxide material such as SiO₂ or a nitride material but is not limited to these dielectric materials.

Using a known oxidation process (e.g., the low temperature plasma oxidation process executed in the range of 300 degrees Celsius), the exposed surfaces of S/D 62B and S/D 62A are oxidized. The low temperature oxidation process forms a thin oxide layer (e.g., in the range of 1 to 5 nm thick, but is typically 3-5 nm thick) for dielectric material 81. The oxidation process forming dielectric material 81 is a self-aligning process that forms the self-limited, thin oxide dielectric layer on the exposed semiconductor material surfaces of S/D 62A and S/D 62B. In other embodiments, dielectric material 81 is formed by the low temperature plasma oxidation process on exposed semiconductor surfaces of other semiconductor device features such as one or more device channels which may be adjacent to later formed metal features of the semiconductor chip. In some embodiments, dielectric material 81 is a nitride material. In these embodiments, the thin layer of nitride such as SiON or SiN can be formed by a plasma nitridation with a thickness in the range of 1-5 nanometers (nm) on the exposed semiconductor material surface of the sidewalls of S/D 62A and S/D 62B and preferably, a 3-5 nm thick layer on S/D 62A and S/D 62B.

Using a known low temperature plasma oxidation process, dielectric material 81 can be formed on the exposed surfaces of left sidewall of S/D 62A, the right sidewall of S/D 62B, and on a portion of the top surface of S/D 62A. In various embodiments, the typical range of the thickness of dielectric material 81 is three to five nm. Dielectric material 81, formed using the low temperature plasma oxidation process, provides a self-aligned layer of dielectric material 81 on any exposed surface of S/D 62A and S/D 62B. In various embodiments, using an etching process such as RIE, dielectric material 81 on the top surface of S/D 62A can be removed exposing the top surface of S/D 62A for later contact or via formation. In various embodiments, at least a portion of one of sidewall S/D 62A or S/D 62B is exposed for oxidation during the low temperature plasma oxidation process to form dielectric material 81 on the exposed portions of S/D 62A and/or S/D 62B. In various embodiments, the exposed surfaces, or portions of S/D 62A and/or S/D 62B are essentially flat and parallel to one or more sidewalls of immediately adjacent via holes. In these embodiments, dielectric material 81, formed by oxidizing the surface of S/D 62A and/or S/D 62B, is parallel to the sidewall of the via hole and forms a flat, vertical portion of the sidewall of the via hole. In other embodiments, a rounded, curved, pointed, rectangular, or any other shaped of the portion of S/D 62A and/or 62B extends into a portion of the adjacent via hole. In some embodiments, a larger portion of S/D 62A and/or S/D 62B extends into the via holes such that portions of the top and/or bottom surfaces of S/D 62A and/or S/D 62B are exposed in FIG. 5C. In these embodiments, in addition to the sidewalls of S/D 62A and S/D 62B, portions of the top and/or bottom surfaces of S/D 62A and 62B are covered with dielectric material 81. As depicted in FIG. 5C, dielectric material 81 on S/D 62A and 62B is essentially flat with a slightly rounded sidewall surface adjacent to and exposed to or in a portion the via holes.

The self-aligned layer of dielectric material 81 prevents any electrical shorting of S/D 62A or S/D 62B with any directly adjacent metal feature such as vias, metal lines, contacts, or backside power vias formed in later processes.

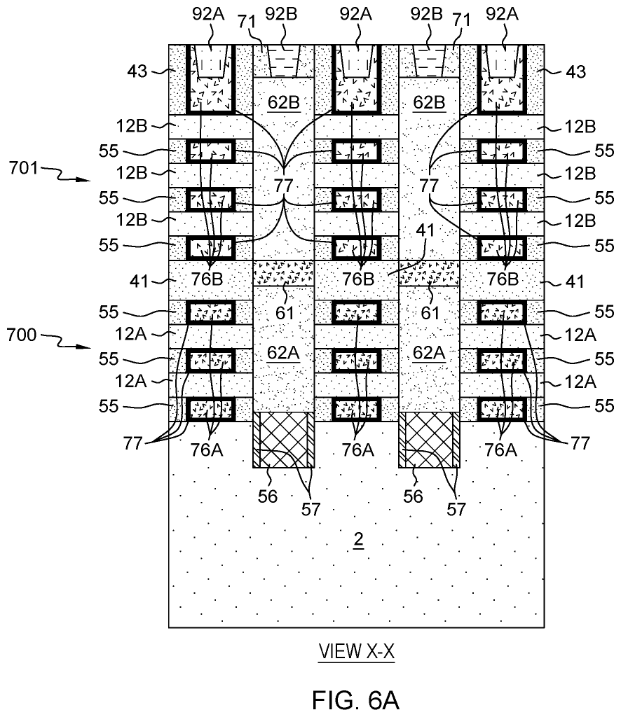

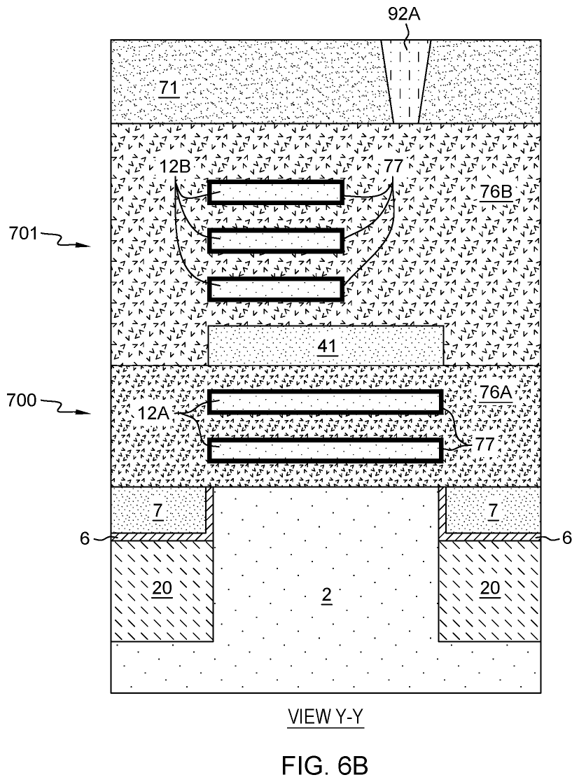

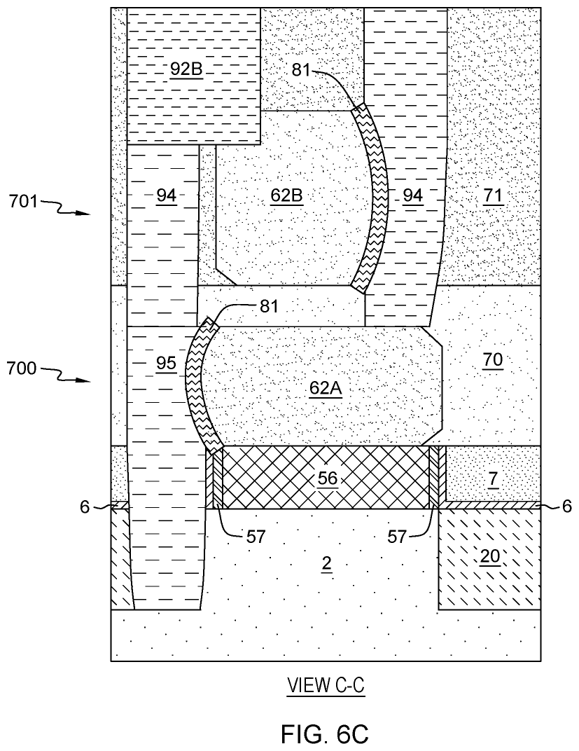

FIG. 6A depicts a cross-sectional view, along section line X of FIG. 1, FIG. 6B depicts a cross-sectional view, along section line Y of FIG. 1, and FIG. 6C depicts a cross-sectional view, along section line C of FIG. 1, of the semiconductor structure after forming a plurality of vias 94, backside power via 95, and contacts 92A and 92B, in accordance with an embodiment of the present invention. In various embodiments, GAA FET 701 is above GAA FET 700 to form two stacked GAA FETs. In some cases, more than two GAA FETs can be vertically stacked. In other embodiments, GAA FET 701 and GAA FET 700 form a CFET (e.g., when GAA FET 701 is an NFET and GAA FET 700 is a PFET or vice versa).

As depicted in FIGS. 6A and 6B, after ILD 71 deposition depicted in FIGS. 5A, 5B, and 5C, contact 92A and contact 92B formation occurs using known semiconductor manufacturing processes for contact formation (e.g., contact via etch, contact metal deposition, and a chemical-mechanical polish (CMP). In FIG. 6A, three of contacts 92A and two of contacts 92B are formed. As depicted, contacts 92A connect to gate metal 76B and contacts 92B connect to one of S/D 62B. As depicted in FIG. 6A, each of contacts 92A contact or reside in one of gate metal 76B and each of contacts 92B contact one of S/D 62B. Contacts 92A and contact 92B reside in the middle-of-line (MOL) semiconductor metallization. In FIG. 6B, a gate contact labeled contact 92A is formed contacting gate metal 76.

As depicted in FIG. 6C, the forming of vias 94 and contact 92B occurs using known via formation and contact formation processes. For example, the via holes or openings depicted in FIG. 5C are filled with one or more known metal materials for vias or contacts such as cobalt, tungsten, or copper. The metal materials are deposited in the holes of FIG. 5C and the metal fills the via holes. A CMP may be performed.

The via or contact metal in the left side opening or via hole after filling the via hole with metal is recessed to the same level as the top surface of S/D 62A. After recessing the metal material, the remaining metal material forms backside power via 95. Backside power via 95 extends from at least the bottom of STI 20 to the top surface of S/D 62A, as depicted in FIG. 6C. Backside power via 95 is in a bottom portion of bottom dielectric 70, in oxide 7, in STI 20, and in some cases, may extend into a top portion of substrate 2. In some cases, after recessing the contact metal to form backside power via 95, the exposed surface of dielectric material 81 formed on S/D 62A is essentially flat and parallel to the via hole.

After recessing the metal material in the via hole and forming backside power via 95, an etch process creates an opening for contact 92B, where the etching process removes a portion of top ILD 71 that exposes a portion of the top surface of S/D 62B and in some cases, may expose portions of the left sidewall of S/D 62B. The top portion of S/D 62B can be exposed. The etched opening or contact hole extends from the removed portion of S/D 62B to the via hole exposed by the metal recessing. Using a dual damascene process, via 94 and contact 92B can be formed. The metal material is deposited in the contact and via holes to create the left most via 94 under contact 92B. A CMP can be performed. Contact 92B connects the leftmost via 94 to S/D 62B. The left most via 94 connects backside power via 95 to contact 92B.

During the via formation processes (e.g., metal deposition in via hole and CMP), the metal material in the right most via hole forms a second right most via 94 that contacts the top surface of S/D 62A and extends to the top surface of ILD 71. Vias 94 and contact 92B reside in the MOL with a top surface that is level with the top surface of ILD 71.

As depicted in FIG. 6C, dielectric material 81 on the right sidewall of S/D 62B prevents shorting between S/D 62B and the rightmost of vias 94. Dielectric material 81 on the left sidewall of S/D 62A prevents shorting between S/D 62A and backside power via 95. As depicted in FIG. 5C, after the low temperature plasma process, there are no exposed sidewall surfaces of S/D 62A or S/D 62B that can contact a metal material such as via 94, backside power via 95 or any other metal feature not depicted in the semiconductor structure of FIG. 6C (e.g., a contact, a portion of metal line, or a metal element of a portion of another adjacent semiconductor device). In this way, as depicted in FIG. 6C, after the creation of backside power via 95 and vias 94, the presence of dielectric material 81 electrically isolates S/D 62A and S/D 62B from backside power via 95 and vias 94. Dielectric material 81 on the sidewalls of S/D 62A and S/D 62B immediately adjacent to the metal material of vias 94 and backside power via 95 forms a spacer electrically isolating the sidewalls of S/D 62A and S/D 62B from the metal material of the vias 94 and backside power via 95.

The thin layer of dielectric material 81 on the exposed surfaces of S/D 62A and S/D 62B allows metal features such as vias 94 and backside power via 95 to be in direct contact with the thin layer (e.g., typically, 3-5 nm) of dielectric material 81 on S/D 62A without creating electrical shorts between S/D 62A and backside power via 95 or S/D 62B and via 94. Forming dielectric material 81 on the exposed sidewalls of S/D 62A and S/D 62B, after via hole etching processes, allows metal features such as via 94 and backside power via 95 to be formed contacting the thin oxide layer of dielectric material 81 without shorting. As previously discussed, in some embodiments, a larger portion of S/D 62A and/or S/D 62B covered by dielectric material 81 extends into vias 94 and/or backside power via 95. Portions of the top and/or bottom surfaces of S/D 62A and/or S/D 62B can be exposed in FIG. 5C and covered by dielectric material 81 during the low temperature plasma processes. In these embodiments, in addition to the sidewalls of S/D 62A and S/D 62B, portions of the top and/or bottom surfaces of S/D 62A and 62B covered with dielectric material 81 and contact portions of vias 94 or backside power via 95. In some cases, the top and/or bottom surfaces of S/D 62A, S/D 62B, or surfaces of another semiconductor element such as a channel covered by dielectric material 81 are electrically isolated from an immediately adjacent metal line, contact, power plane, or a portion of an adjacent semiconductor device.

Conventionally formed adjacent stacked GAA FETs have a layer of an insulating material such as an ILD material between the source/drains and metal vias. The layer of ILD between adjacent conventional stacked GAA FETs is typically thicker than dielectric material 81.

Using the thin layer (e.g., 3-5 nm thick) of dielectric material 81 formed by a low temperature plasma oxidation process on the sidewalls of S/D 62A and S/D 62B allows tighter pitches or less space between S/D 62A and backside power via 95 and between S/D 62B and via 94 than conventionally formed stacked GAA FETs or CFETs.

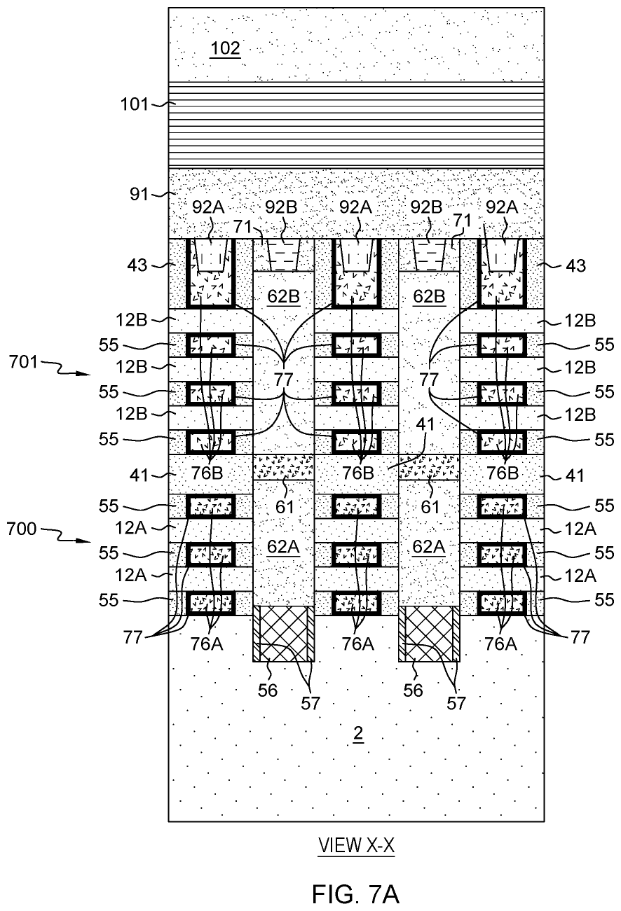

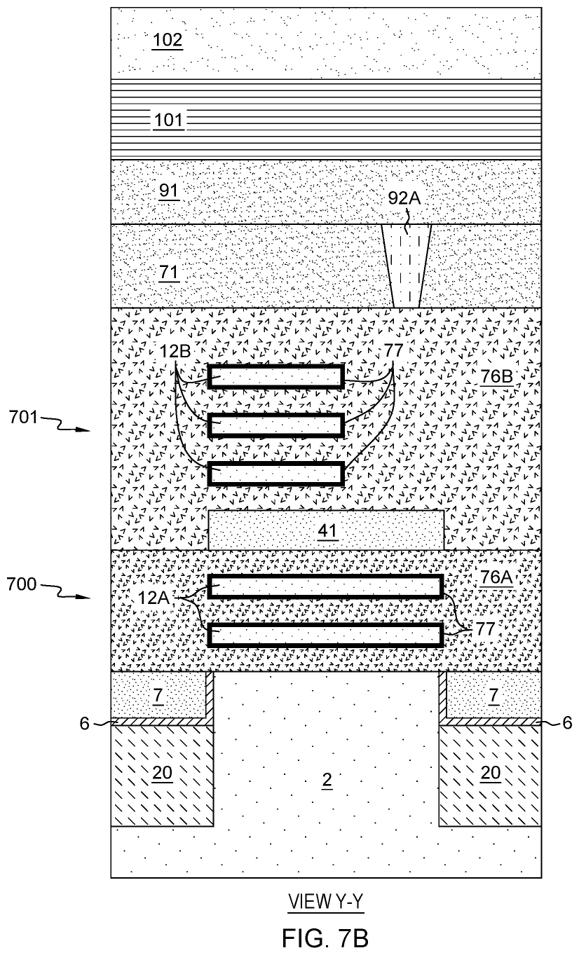

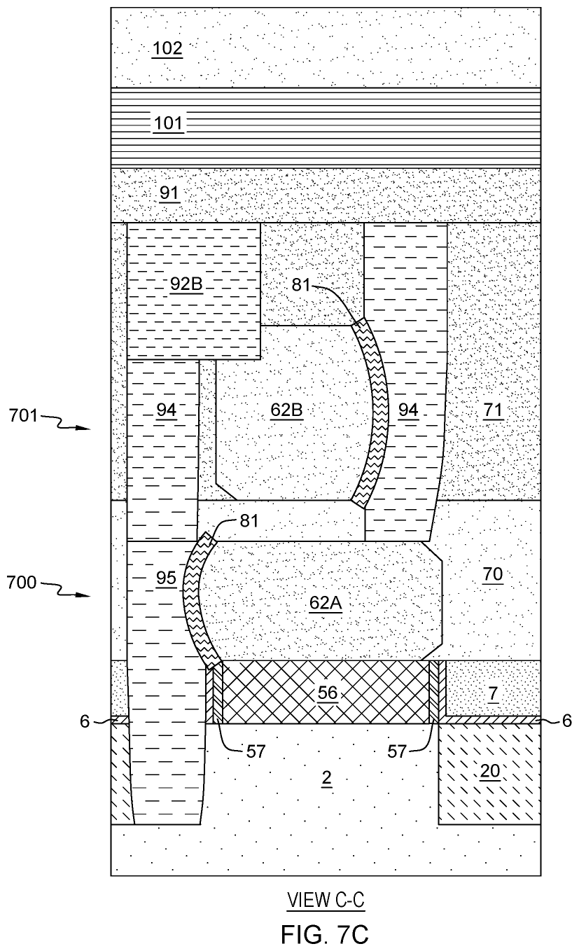

FIG. 7A depicts a cross-sectional view, along section line X of FIG. 1, FIG. 7B depicts a cross-sectional view, along section line Y of FIG. 1, and FIG. 3C depicts a cross-sectional view, along section line C of FIG. 1 of the semiconductor structure after forming one or more of layers of interconnects 91, frontside interconnect wiring 301, and bonding carrier wafer 302 to frontside interconnect wiring 301, in accordance with an embodiment of the present invention. Using known semiconductor manufacturing processes such as ILD deposition, via and contact etching, metal deposition for vias and/or contacts, and CMP, one or more layers of ILD, via contacts, and lines may be form one or layers of interconnects 91 on the top surface of ILD 71 contacts 92A, and contacts 92B. As known by one skilled in the art and as depicted in FIGS. 7A, 7B, and 7C, the layers of interconnects 91 which include at least one layer of ILD with contact vias, connect each of contacts 92A and 92B to frontside interconnect wiring 101. Interconnects 91 provide connections between MOL layers of the semiconductor structure and frontside interconnect wiring 301. After forming interconnects 91, using known frontside back-end-of-line (BEOL) semiconductor manufacturing processes, frontside interconnect wiring 101 can be formed on the layers of interconnects 91. As depicted in FIGS. 7A, 7B, and 7C, after forming frontside interconnect wiring 101, carrier wafer 102 bonds to frontside interconnect wiring 101.

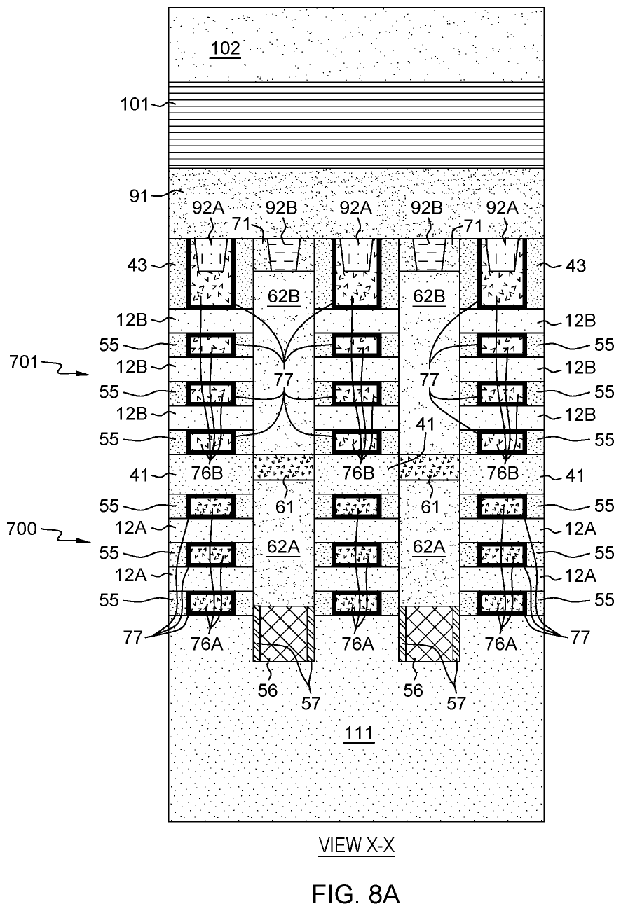

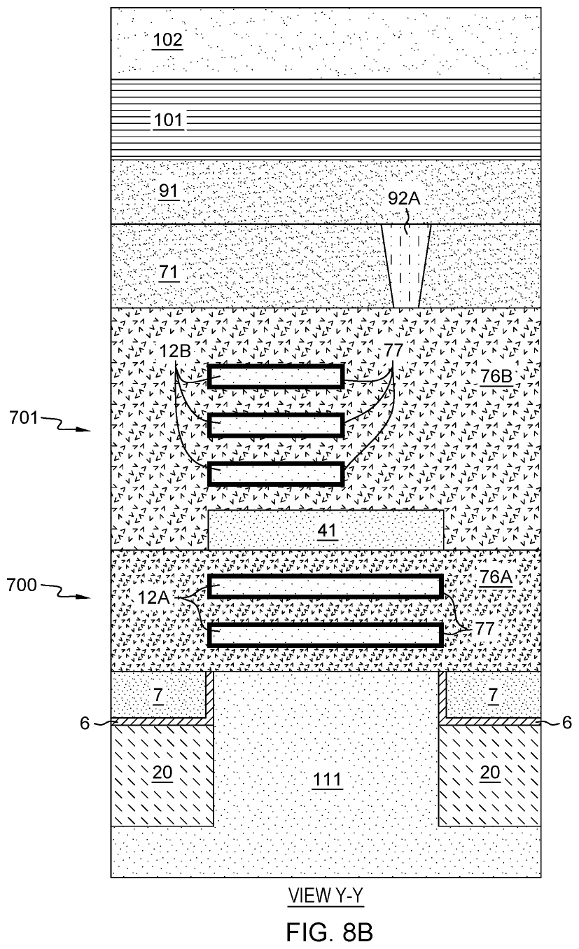

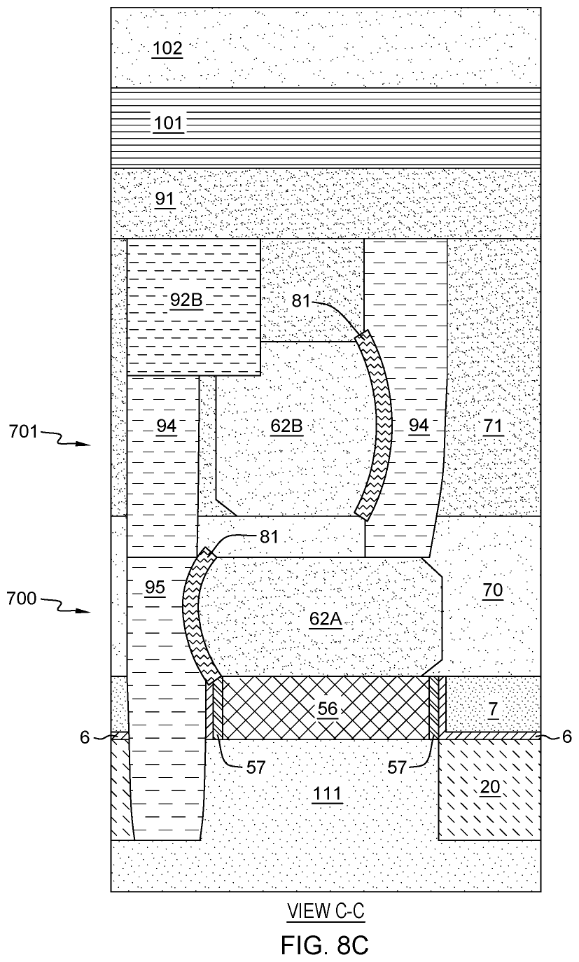

FIG. 8A a cross-sectional view, along section line X of FIG. 1, FIG. 8B depicts a cross-sectional view, along section line Y of FIG. 1, and FIG. 8C depicts a cross-sectional view, along section line C of FIG. 1 of the semiconductor structure after removing substrate 2 and depositing BILD 111, in accordance with an embodiment of the present invention. Using known semiconductor manufacturing processes, substrate 2 is removed and BILD 111 deposits under one or more of STI 20, backside power via 95, placeholders 56, inner spacers 55, and gate dielectric 77 as depicted in each of FIGS. 8A, 8B, and 8C.

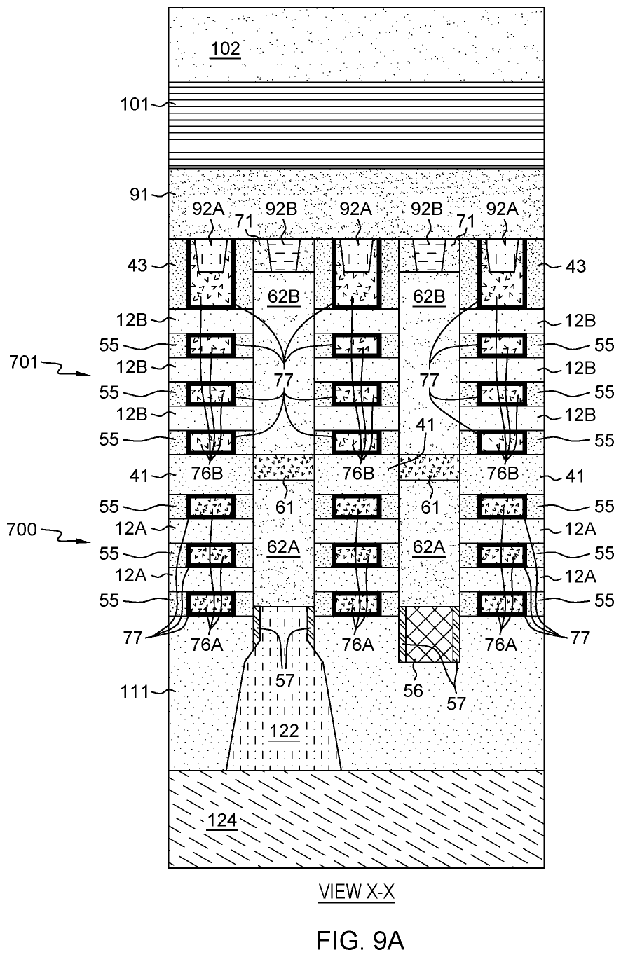

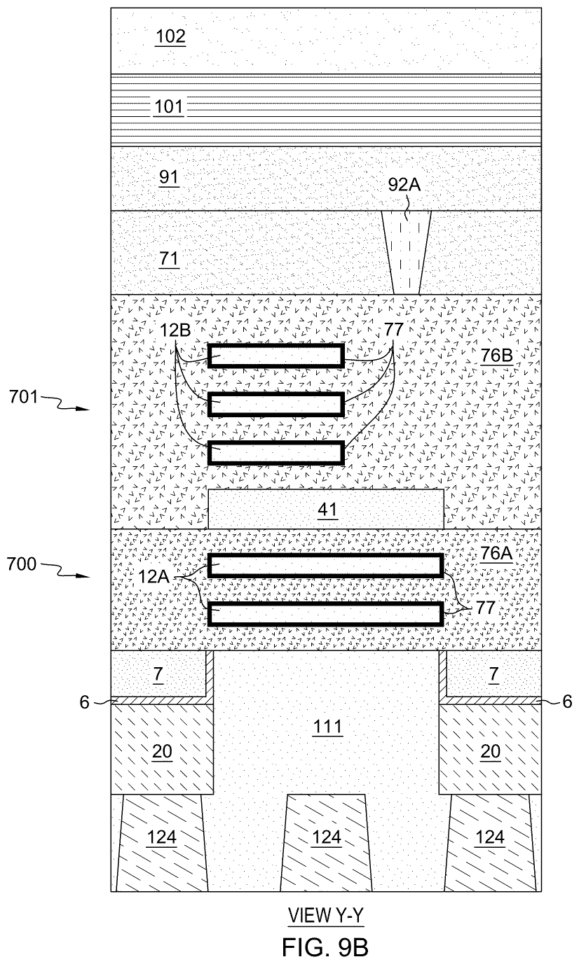

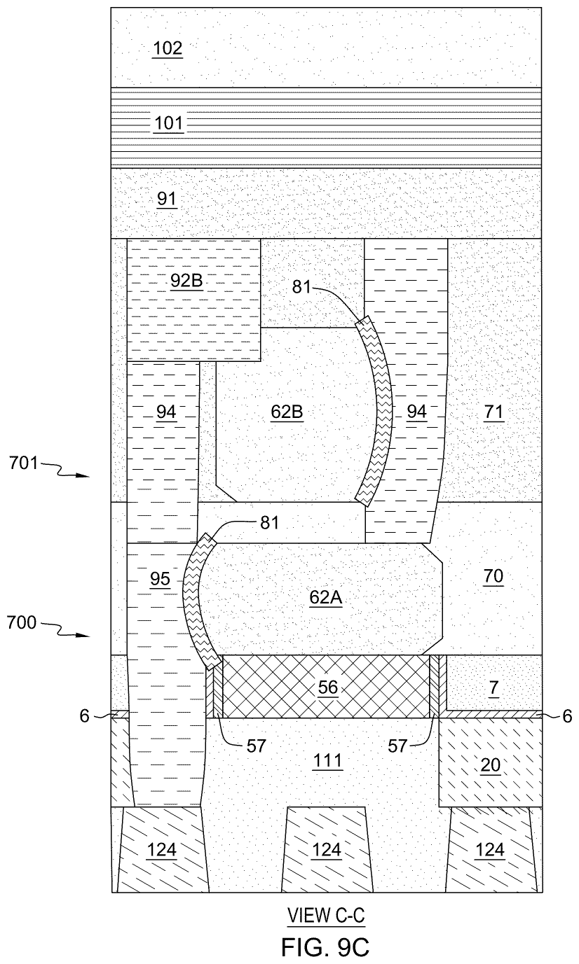

FIG. 9A depicts a cross-sectional view, along section line X of FIG. 1, FIG. 9B depicts a cross-sectional view, along section line Y of FIG. 1, and FIG. 9C depicts a cross-sectional view, along section line C of FIG. 1, the semiconductor structure after forming backside contact 122 and backside metal layer 124, in accordance with an embodiment of the present invention. FIG. 9A, FIG. 9B, and FIG. 9C depict various cross-sectional views of two vertically stacked GAA FETs (i.e., GAA FET 700 and GAA FET 701) where the very thin (e.g., 4-6 nm thick) layer of an oxide material such as dielectric material 81 resides on at least one source/drain (e.g., S/D 62A or S/D 62B) of a top GAA FET (e.g., GAA FET 701) and a bottom GAA FET (e.g., GAA FET 700) where the oxide is formed by a low temperature oxidation process to be a sidewall spacer on the source/drain that contacts a metal feature such as a via. In other embodiments, more than two GAA FETs are vertically stacked. In these embodiments with more than two stacked GAA FETs, where one or more of the source/drains in one or more of the stacked GAA FETs have at least one sidewall with the oxide dielectric material (e.g., dielectric material 81) for a sidewall spacer on the at least one sidewall of the source/drains of the GAA FETs.

In FIG. 9A, using known backside contact formation processes, backside contact 122 can be formed in BILD 111 contacting the leftmost S/D 62A. After forming backside contact 122, backside metal layer 124 is deposited (e.g., copper) contacting backside contact 122. In FIG. 9B, backside metal layer 124 can be deposited and patterned in BILD 111 and on STI 20. In FIG. 9C, backside metal layer 124 can be deposited and patterned so that at least one portion of backside metal layer 124 contacts backside power via 95.

In FIG. 9C, interconnects 91 connect contact 92B and the right via 94 to frontside interconnect wiring 101 under carrier wafer 102. Contact 92B connects S/D 62B to via 94. The left via 94 connects contact 92B to backside power via 95 where backside power via 95 connects to backside metal layer 124. The right via 94 connects S/D 62A to interconnects 91 and frontside interconnect wiring 101. As depicted in FIG. 9C, S/D 62A is separated from backside power via 95 by dielectric material 81 and S/D 62B is separated from the right via 94. The very thin layer of dielectric material 81 on surfaces of S/D 62A and 62B exposed during via hole etch are electrically insulated and isolated from the metal material of backside power via 95 and via 94, respectively.

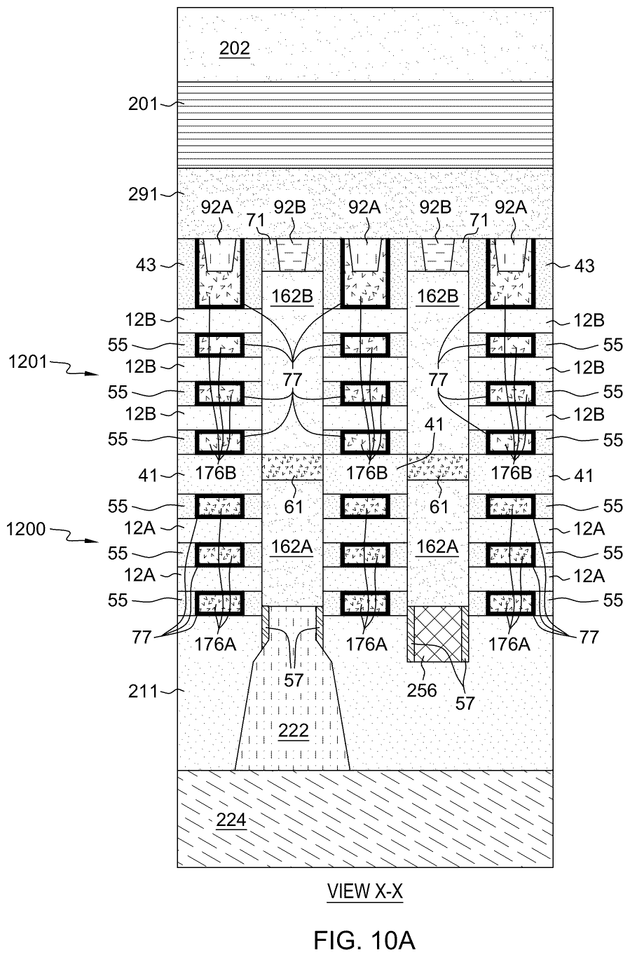

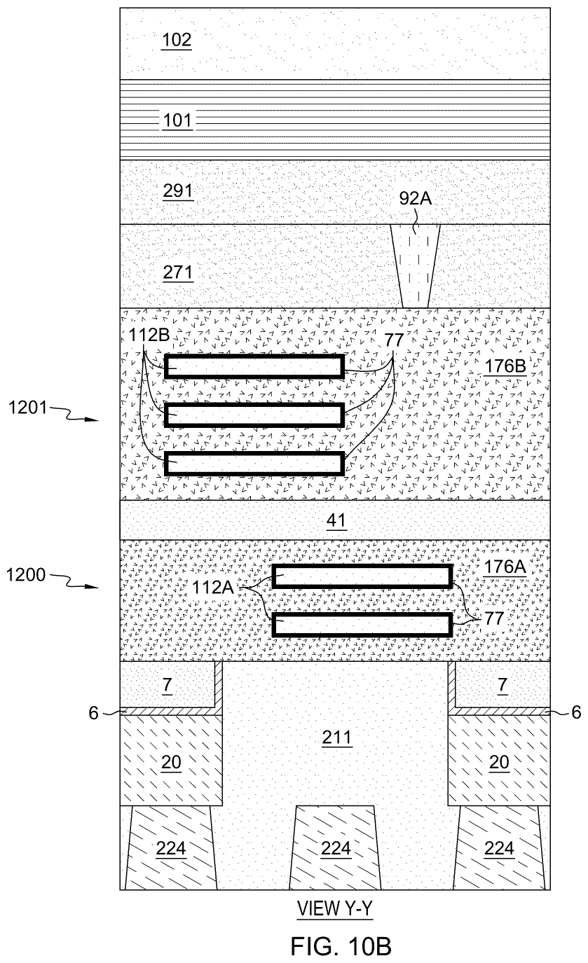

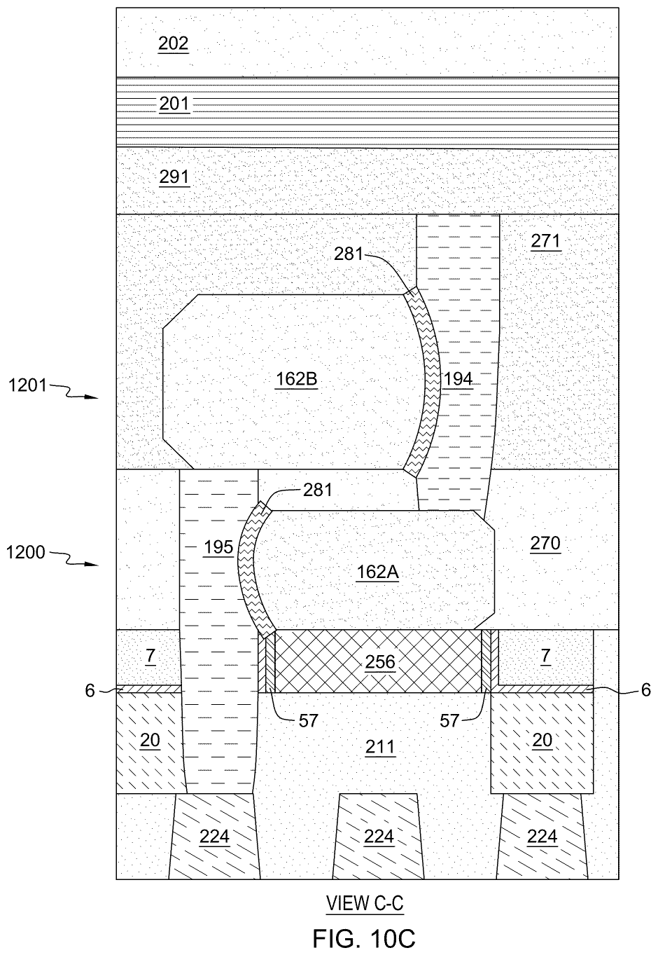

FIG. 10A depicts a cross-sectional view, along section line X of FIG. 1, FIG. 10B depicts a cross-sectional view, along section line Y of FIG. 1, and FIG. 10C depicts a cross-sectional view, along section line C of FIG. 1 of a semiconductor structure with two staggered, stacked semiconductor devices, in accordance with an embodiment of the present invention. In various embodiments, FIGS. 10A, 10B, and 10C depict two staggered GAA FETs (e.g., top GAA FET 1201 and bottom GAA FET 1200) where in FIG. 10C, backside power via 195 connects the bottom surface of S/D 162B to backside metal layer 224. Top GAA FET 1201 and bottom GAA FET 1200, in some embodiments, form a CFET. In FIGS. 10A, 10B, and 10C, backside metal layer 224 like backside metal layer 124 of FIGS. 9A, 9B, and 9C may be a portion of a backside power delivery network. As depicted, FIGS. 10A, 10B, and 10C include carrier wafer 202 on frontside interconnect wiring 201 with one or more layers of interconnects 291 connecting contacts 92A and 92B to frontside interconnect wiring 201.

As depicted in FIG. 10A, top GAA FET 1201 includes at least top S/D 162B, channels 112B, gate metal 176B, gate dielectric 77, inner spacers 55, gate spacer 43 above MDI 41, and bottom GAA FET 1200 includes at least S/D 162A, channels 112A, gate metal 176A, gate spacer 43, with gate dielectric 77 and inner spacers 55 under MDI 41 and on BILD 111. Backside contact 222 connects S/D 162A to backside metal layer 224. Also, as depicted in FIG. 10A, placeholder 256 resides below the rightmost S/D 162A.

As depicted in FIG. 10B, channels 112B in top GAA FET 1201 are staggered or shifted to the left above channels 112A of bottom GAA FET 1200. In FIG. 10B, the horizontal width of channels 112B in top GAA FET 1201 and the horizontal width of channels 112A in bottom GAA FET 1200 are approximately the same. In other embodiments, the width of channels 112A and channels 112B is different. As depicted in FIG. 10B, top GAA FET 1201 is staggered over bottom GAA FET 1200 (e.g., none of the sidewalls of channels 112B are vertically aligned with the sidewalls of channels 112A). In other words, top GAA FET 1201 with a same channel width as bottom GAA FET 1200 is staggered over and to the left of bottom GAA FET 1200. MDI 41 can be between top GAA FET 1201 and bottom GAA FET 1200. FIG. 10B also includes oxide 7, STI 20 BILD 211, and backside metal layer 224 that are depicted below metal gate 276A.

As depicted in FIG. 10C, S/D 162B in top GAA FET 1201 is shifted to the left of S/D 162A in bottom GAA FET 1200. S/D 162A connects by via 194 to contact 92A and S/D 162B connects by backside power via 195 to backside metal layer 224. In FIG. 10C, the vertical thickness of S/D 162B is greater than S/D 162A however, in other examples, S/D 162A is thicker than S/D 162B. In various embodiments, when S/D 162A and S/D 162B have different thicknesses, separate plasma oxidation processes may occur. In other cases, when the thickness of S/D 162A and 162B are the same, a single plasma oxidation process can provide the layer of dielectric material 81. Also, depicted in FIG. 10C, placeholder 256 resides below S/D 162A and oxide 7, STI 20, reside below ILD 270.

The right sidewall of S/D 162B is covered by dielectric material 281. Dielectric material 281 electrically isolates the right sidewall of S/D 162B from via 194. Dielectric material 281 on the left sidewall of S/D 162A electrically isolates the left sidewall of S/D 162A from backside power via 195. Dielectric material 281 can be formed by oxidation on the exposed surfaces of S/D 162A and S/D 162B, which may include portions of the bottom or top surfaces of S/D 162A and 162B, after backside power via etching and via hole etching using the processes previously discussed with respect to FIGS. 1-9A, 9B, and 9C. Dielectric material 281 can be formed on exposed S/D surfaces using the previously discussed low temperature plasma oxidation process to electrically isolate S/D 162A and 162B from conductive materials such as via 194, backside power via 95 or other metal elements not depicted in FIG. 10C (e.g., contact metals, metal lines, or metal elements on another adjacent semiconductor device). The portion of dielectric material 281 formed on the top surface of S/D 162A is removed before the formation of via 194.

In FIGS. 10A, 10B, and 10C, include one or more layers of interconnects 291 over ILD 271 and contacts 92A and 92B where the layers of interconnects 291 connect each of contacts 92A and 92B with frontside interconnect wiring 201. A top layer of frontside interconnect wiring 201 can be bonded to carrier wafer 202.

FIG. 11 depicts a cross-sectional view through a gate cut similar to section line C of the top view of FIG. 1 of a semiconductor structure with four GAA FETs where two of the top GAA FETs are each stacked on a bottom GAA FET, in accordance with an embodiment of the present invention. The gate cut of FIG. 11 is parallel to and between adjacent gates of the stacked GAA FETs.

In FIG. 11, top GAA FET 1501A is stacked on bottom GAA FET 1500A and top GAA FET 1501B is stacked on bottom GAA FET 1500B. Top GAA FET 1501A is depicted to the left of via 294 and bottom GAA FET 1500A is depicted to the left of backside power via 495. In FIG. 11, S/D 262A of top GAA FET 1501A directly contacts contact 192A. Top GAA FET 1501B is depicted to the right of via 294 and bottom GAA FET 1500B is depicted to the right of backside power via 495 where S/D 262B of top GAA FET 1501B also directly contacts contact 192B. Each of contacts 192A and contact 192B also connect vias 294 to one or more layers of interconnects 391. Interconnects 391 connect each of contacts 192A and 192B to frontside interconnect wiring 301. Carrier wafer 302 bonds to frontside interconnect wiring 301. Also, as depicted in FIG. 11, two of placeholder 256 on directly backside ILD 311. One of placeholder 256 resides directly below each of S/D 362A and S/D 362B.

FIG. 11 depicts the rightmost top GAA FET 1501B with S/D 262B where S/D 262B has a rightmost sidewall covered by dielectric material 381. Dielectric material 381 electrically isolates S/D 262B from the rightmost via 294. As previously discussed, dielectric material 381 can be formed on exposed S/D 262B surfaces after via hole with etching using the low temperature plasma process after etching a vial hole for via 294.

Similarly, FIG. 11 depicts top GAA FET 1501A with a leftmost sidewall of S/D 262A covered by dielectric material 381. In top GAA FET 1501A, dielectric material 381 electrically isolates S/D 262A from the leftmost via 194. Top GAA FET 1500A and 1500B connect to frontside interconnect wiring 301 by the contact 192A using interconnects 391. S/D 262A and 262B of top GAA FET 1501A and 1501B, respectively, connect by the center via of vias 294 to backside metal 324 by backside power via 495. Backside metal 324 can be a portion of a backside power delivery network.

FIG. 11 depicts bottom GAA FET 1500A with a right sidewall of S/D 362A covered by dielectric material 381. Dielectric material 381 electrically isolates S/D 362A from backside power via 495. Similarly, FIG. 11 depicts bottom GAA FET 1500A with dielectric material 381 covering a right sidewall of S/D 362A electrically isolating S/D 362A from backside power via 495. In bottom GAA FET 1500B, dielectric material 381 electrically isolates S/D 362B from backside power via 495.

FIG. 11 depicts top GAA FET 1501A and top GAA FET 1501B with facing S/D 262A and S/D 262B sidewalls that are adjacent to the center via 294 but isolated from center via 294 by dielectric material 381. The facing sidewalls of S/D 262A in top GAA FET 1501A and S/D 262B in top GAA FET 1501B are approximately, vertically aligned over the center or facing sidewalls S/D 362A of bottom GAA FET 1500A and S/D 362B of bottom GAA FET 1500B, respectively. The center contact 192B connects to each of S/D 262A and S/D 262B.

As depicted in FIG. 11, forming dielectric material 381 as a thin oxide layer (e.g., 3-5 nm) on the sidewalls of S/D 362A and S/D 362B directly adjacent to or contacting backside power via 495 allows densely packed bottom GAA FETs as the thin layer of dielectric material 381 ensures that neither of S/D 362A or 362B will short to backside power via 495. In some embodiments, the facing right and left sidewalls S/D 262A and S/D 262B, respectively, contact portions of the center via 294. In other embodiments, the facing sidewalls of S/D 262A and S/D 262B are separated from the center via 294 by a thin strip or layer of ILD 71. Center via 294 connects backside power via 495 to frontside interconnect wiring 301 by S/D 92B and various via connections and/or lines in interconnects 391.

In various embodiments, Similarly, each via 294 of the two outside vias adjacent to opposing sidewalls of S/D 262A and S.D 262B are electrically isolated by the thin layer (e.g., 3-5 nm) of dielectric material 381 from S/D 262A and S/D 262B (i.e., the right via 294 is isolated from the right sidewall of S/D 262B and left via 294 is isolated from the left sidewall of S/D 262A by dielectric material 381).

As depicted in FIG. 11, the two L-shaped, stacked GAA FETs can be tightly packed or designed with a very small pitch between the two L-shaped stacked GAA FETs. The first L-shaped stacked GAA FET is composed of top GAA FET 1501A over bottom GAA FET 1500A where S/D 262A has a narrower width than the width of S/D 362A below it. The second L-shaped stacked GAA FET is composed of top nanosheet GAA FET 1501B over bottom nanosheet GAA FET 1500B where S/D 262B has a narrower width than the width of S/D 362B below it. As depicted in FIG. 11, the bottom source/drains (i.e., S/D 362A and 362B) located on either side of backside power via 495 have a wider horizontal width. The facing sidewalls of S/D 362A and 362B covered by dielectric material 381 are approximately vertically aligned under the facing sidewalls of S/D 262A and S/D 262B of top GAA FET 1501A and top GAA FET 1501B, respectively. FIG. 11 illustrates the ability to form four GAA FETS in created as two sets of two vertically stacked GAA FETS (i.e., one set composed of top GAA FET 1501A and bottom GAA FET 1500A and the second set composed of top GAA FET 1501B and bottom GAA FET 1500B) where forming dielectric material 381 on at least the sidewalls of S/D 262A, S/D 262B, S/D 362A,

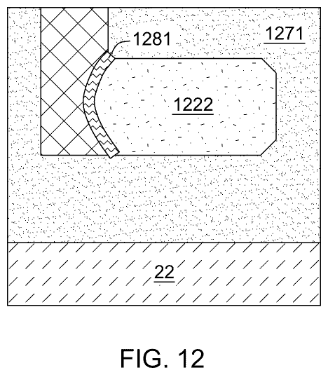

FIG. 12 depicts a cross-sectional view of a semiconductor structure after forming metal element 1284 in ILD 1271 directly contacting dielectric material 1281 on semiconductor material 1222, in accordance with an embodiment of the present invention. In various embodiments, semiconductor material 1222 which can be any portion of a semiconductor material in a semiconductor device or a portion of semiconductor material in a photovoltaic cell. In some embodiments, layer 22 is a portion of one of a semiconductor substrate or a metal layer. In some embodiments, semiconductor material 1222 is a portion of one or more semiconductor elements such as a channel, a source/drain, a semiconductor substrate, or a capacitor in a semiconductor device such as any logic device, a FET, a photovoltaic cell, a memory cell, or a memory device,

Using the known semiconductor processes as discussed with respect to FIG. 1 through FIGS. 10A, 10B, and 10C, FIG. 12 includes dielectric material 1281 on semiconductor material 1222. In some embodiments, semiconductor material 1222 is a source/drain. In other embodiments, semiconductor material 1222 is a channel of a semiconductor device such as but not limited to a GAA FET, a planar FET, CFET, a finFET, or forksheet FET. In other embodiments, semiconductor material 1222 is a portion of a photovoltaic cell or a solar photovoltaic cell device where one of an oxide dielectric material or a nitride dielectric material can be formed as a thin layer (1-5 nm thick) of dielectric material 1281 on any exposed semiconductor material 1222 surface when performing the low temperature plasma process previously discussed.

As depicted at least a portion of metal element 1284 directly adjacent to semiconductor material 1222 is electrically isolated from semiconductor material 1222 by dielectric material 1281 when a portion of semiconductor material 1222 directly covered by dielectric material 1281 extends into a portion of metal element 1284. In various embodiments, metal element 1284 is a via. In other embodiments, metal element 1284 is a portion of a metal layer such as a signal line, a power line, or a power plane. In an embodiment, metal element 1284 is a portion of a directly adjacent resistor, another adjacent semiconductor device, or another adjacent photovoltaic cell where the portion of semiconductor material 1222 covered by dielectric material 1281 extends into metal element 1284. In these cases, dielectric material 1281 electrically isolates the portion of semiconductor material 1222 extending into metal element 1284 as depicted in FIG. 12.

Using the method and semiconductor manufacturing processes discussed with respect to FIG. 1 through FIGS. 9A, 9B, and 9C, the elements of FIG. 12 can be formed such that semiconductor material 1222 is electrically isolated by dielectric material 1281 from metal element 1284 which can be any metal element or feature in a semiconductor chip or photovoltaic cell. The low temperature, self-aligned and self-limiting plasma oxidation or nitridation processes, as discussed above, of the exposed semiconductor surfaces of semiconductor material 1222 allows densely packed CMOS logic devices, densely packed stacked FET devices as discussed above, densely packed memory devices, or densely packed photovoltaic cells. Using the processes previously discussed to form dielectric material 1281 (or dielectric material 81) on the exposed portions of semiconductor material 1222 (e.g., a source/drain or a channel) extending into to an opening or a via hole, electrically isolates a via or other metal element deposited in the via hole or opening from semiconductor material 1222. Using this method allows semiconductor devices to be densely packed without any dimensional shrinking of directly adjacent metal elements 1284 such as metallized contacts, vias, or lines. Providing a thin layer of dielectric material 1281 insulating semiconductor material 1222 from metal element 1282 allows tight packing or densely packed semiconductor devices in any type of suitable semiconductor device to be formed without electrical shorting between metal element 1284 and semiconductor material 1222.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a semiconductor element of a semiconductor device, wherein a portion of the semiconductor element extends into a metal element; and
a dielectric material on the portion of the semiconductor element contacts the metal element.

2. The semiconductor structure of claim 1, wherein the semiconductor element is a source/drain of a field-effect transistor.

3. The semiconductor structure of claim 1 wherein the dielectric material on the portion of the semiconductor element is a spacer.

4. The semiconductor structure of claim 1, wherein the dielectric material on the portion of the semiconductor element has a thickness ranging from three to five nanometers.

5. The semiconductor structure of claim 2, wherein the field-effect transistor is at least one field-effect transistor of two vertically stacked field-effect transistors.

6. The semiconductor structure of claim 5, wherein each of the two vertically stacked field-effect transistors are a vertically stacked gate-all-around field-effect transistor, wherein each of the vertically stacked gate-all-around field-effect transistor have a sidewall of the source/drain covered by the dielectric material.

7. The semiconductor structure of claim 6, further comprising the metal element is at least one via directly contacting the dielectric material, and wherein the dielectric material electrically isolates the at least one via from the sidewall of the source/drain of each of the two vertically stacked gate-all-around field-effect transistors.

8. The semiconductor structure of claim 7, further comprises:
a first source/drain of a bottom gate-all-around field-effect transistor connecting by a backside contact to a backside metal layer; and
a second source/drain of a bottom gate-all-around field-effect transistor connecting by the backside contact to the backside metal layer.

9. The semiconductor structure of claim 8, further comprises:
a plurality of source/drain contacts to a plurality of source/drains of a top gate-all-around field-effect transistor, where each of the plurality of source/drain contacts connect the plurality of source/drains of the top gate-all-around field-effect transistor by one or more contact vias in one or more interconnect layers to frontside interconnect wiring.

10. The semiconductor structure of claim 9, further comprises:
each of a plurality of gate contacts each connect to a gate structure of the top gate-all-around field-effect transistor, wherein each of the plurality of gate contacts connect by the one or contact vias to the frontside interconnect wiring; and
each of a plurality of source/drain contacts to a source/drain of a plurality of source/drains of the top gate-all-around field-effect transistor connect to the frontside interconnect wiring by the one or more contact vias.

11. The semiconductor structure of claim 1, wherein the metal element is at least one element selected from the group of consisting a contact, a via, and a line, and wherein the semiconductor element is at least one element selected from the group consisting of a channel, a layer of a capacitor, a substrate, and a source/drain.

12. A semiconductor structure comprising:
a first L-shaped stacked gate-all-around field-effect transistor composed of a first top gate-all-around field-effect transistor over a first bottom gate-all-around field-effect transistor, wherein a top source/drain of the first top gate-all-around field-effect transistor has a narrower width than a width of a bottom source/drain of the first bottom gate-all-around field-effect transistor;
a second L-shaped stacked gate-all-around field-effect transistor composed of a second top stacked gate-all-around field-effect transistor over a second stacked gate-all-around field-effect transistor, wherein the top source/drain has a narrower width than the width of a bottom source/drain;
the top source/drain of the first top gate-all-around field-effect transistor has a dielectric material on a left sidewall, wherein the dielectric material contacts a left via and a right sidewall of the top source/drain contacts a dielectric material contacting a center via; and
the bottom source/drain of the first bottom gate-all-around field-effect transistor has the dielectric material on the right sidewall, wherein the dielectric material contacts a backside power via connecting to a backside metal layer.

13. The semiconductor structure of claim 12, further comprises:
the top source/drain of the second L-shaped gate-all-around field-effect transistor has the dielectric material on the right sidewall, wherein the dielectric material contacts a right via; and
the bottom source/drain of the second L-shaped gate-all-around field-effect transistor has the dielectric material on the left sidewall, wherein the dielectric material contacts the backside power via connecting to the backside metal layer.

14. The semiconductor structure of claim 12, wherein the dielectric material has a thickness of three to five nanometers on the first top source/drain and the first bottom source/drain.

15. The semiconductor structure of claim 12, wherein the center via resides on the backside power via, and wherein the center via connects a top source/drain contact to the backside power via.

16. The semiconductor structure of claim 13, further comprises:
a plurality of source/drain contacts and a plurality of gate contacts connect by an interconnect layer to frontside interconnect wiring; and
a carrier wafer bonded to the frontside interconnect wiring.

17. A method of forming a conformal, self-aligned dielectric material on a source/drain comprising:
forming two vertically stacked gate-all-around transistors using known nanosheet gate-all-around transistor semiconductor manufacturing processes, wherein a bottom source/drain of a bottom gate-all-around transistor is wider than a top source/drain of a top gate-all-around transistor;
etching a first via hole down to a top surface of the bottom gate-all-around transistor, wherein a top source/drain of the top gate-all-around transistor extends into a portion of the via hole;
performing a low temperature plasma process on the two vertically stacked gate-all-around transistors, wherein the low temperature plasma process forms a layer of a dielectric material on exposed surfaces of the top source/drain of the top gate-all-around transistor extending into the portion of the via hole;
depositing a metal material in the via hole, wherein the metal material is isolated from the top source/drain by the layer of the dielectric material; and
forming a via contacting a top surface of a bottom source/drain of the bottom gate-all-around transistor, wherein the layer of the dielectric material isolates the top source/drain extending into a portion of the via from the metal material forming the via.

18. The method of claim 17, wherein the low temperature plasma process forms the layer of the dielectric material on exposed surfaces of the top source/drain forms a dielectric spacer composed of an oxide material.

19. The method of claim 18, wherein the low temperature plasma process is a self-aligning and a self-limiting process that forms the layer of the dielectric material with a thickness ranging from one to five nanometers on a sidewall of the top source/drain.

20. The method of claim 17, further comprising:
forming a contact connecting the first via to one or more frontside interconnect wiring layers; and
forming a first backside metal layer connecting to the second via, wherein the first backside metal layer is a portion of a backside power delivery network.
